(19) United States
(12) Patent Application Publication
(10) Pub. No.: US 2025/0081693 A1
(43) Pub. Date: Mar. 6, 2025

(54) Display Device

(71) Applicant: LG Display Co, Ltd., Seoul (KR)

(72) Inventors: Yanghwan Kim, Seoul (KR); HeeJin Im, Goyang-si (KR)

(21) Appl. No.: 18/733,710

(22) Filed: Jun. 4, 2024

(30) Foreign Application Priority Data
Aug. 29, 2023 (KR) 10-2023-0113441

(51) Int. Cl. H01L 33/60; H01L 25/16

(52) U.S. Cl. CPC H10H 20/856; H01L 25/167

(57) ABSTRACT

Provided is a display device. The display device comprises a substrate, a light emitting diode disposed on the substrate, a plurality of patterns which is disposed on the light emitting diode and has a ring shape, and a cover layer on the plurality of patterns, wherein the light emitting diode is a micro light emitting diode (micro LED).

### CROSS-REFERENCE TO RELATED APPLICATIONS

This application claims the priority to and the benefit of Republic of Korea Patent Application No. 10-2023-0113441 filed on Aug. 29, 2023, which is incorporated herein by reference in its entirety.

### BACKGROUND

### Field

The present disclosure relates to a display device, and more particularly, to a display device using a light emitting diode (LED).

### Description of the Related Art

As display devices which are used for a monitor of a computer, a television, a cellular phone, or the like, there are an organic light emitting display (OLED) device which is a self-emitting device, a liquid crystal display (LCD) device which requires a separate light source, and the like.

An applicable range of the display device is diversified to personal digital assistants as well as monitors of computers and televisions and a display device with a large display area and a reduced volume and weight is being studied.

Further, recently, a display device including a light emitting diode (LED) is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast lighting speed, excellent luminous efficiency, and a strong impact resistance so that a stability is excellent and an image having a high luminance can be displayed.

### SUMMARY

An object to be achieved by the present disclosure is to provide a display device with an increased front luminance.

Another object to be achieved by the present disclosure is to provide a display device which improves a luminance deviation according to a viewing angle.

Another object to be achieved by the present disclosure is to provide a display device which improves a mura phenomenon.

Another object to be achieved by the present disclosure is to provide a display device with a high luminance.

Objects of the present disclosure are not limited to the above-mentioned objects, and other objects, which are not mentioned above, can be clearly understood by those skilled in the art from the following descriptions.

According to an aspect of the present disclosure, there is provided a display device. The display device comprises a substrate, a light emitting diode disposed on the substrate, a plurality of patterns which is disposed on the light emitting diode and has a ring shape, and a cover layer on the plurality of patterns, wherein the light emitting diode is a micro light emitting diode (micro-LED).

According to another aspect of the present disclosure, there is provided a display device. The display device comprises a substrate, a plurality of transistors disposed on the substrate, a plurality of light emitting diodes which is connected to the plurality of transistors and is disposed on the plurality of transistors, a protection layer disposed on the plurality of light emitting diodes, and a plurality of patterns which is disposed on the protection layer so as to correspond to the plurality of light emitting diodes, wherein the plurality of light emitting diodes is micro light emitting diodes (micro LEDs).

Other detailed matters of the exemplary embodiments are included in the detailed description and the drawings.

According to the present disclosure, a plurality of patterns is disposed on the light emitting diode to improve a light extraction efficiency.

According to the present disclosure, a shape of the plurality of patterns is changed according to a luminance distribution of the light emitting diode to minimize (or at least reduce) the luminance deviation according to viewing angles.

According to the present disclosure, a shape of the plurality of patterns is adjusted to improve the front luminance.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic diagram of a display device according to an exemplary embodiment of the present disclosure;

FIG. 2 is a cross-sectional view of a pixel area of a display device according to an exemplary embodiment of the present disclosure;

FIG. 3 is a plan view of a plurality of patterns of a display device according to an exemplary embodiment of the present disclosure;

FIGS. 4A and 4B are graphs for explaining an effect of a display device according to an exemplary embodiment of the present disclosure;

FIGS. 5A to 5C are graphs for explaining an effect of a display device according to an exemplary embodiment of the present disclosure;

FIG. 6 is a cross-sectional view of a pixel area of a display device according to another exemplary embodiment of the present disclosure;

FIG. 7 is a cross-sectional view of a pixel area of a display device according to still another exemplary embodiment of the present disclosure;

FIG. 8 is a cross-sectional view of a pixel area of a display device according to still another exemplary embodiment of the present disclosure;

FIG. 9 is a plan view of a plurality of patterns of a display device according to still another exemplary embodiment of the present disclosure;

FIGS. 10A and 10B are schematic plan views of a display device according to still another exemplary embodiment of the present disclosure;

FIGS. 11A and 11B are graphs for explaining an effect of a display device according to still another exemplary embodiment of the present disclosure; and

FIG. 12 is a cross-sectional view of a pixel area of a display device according to still another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

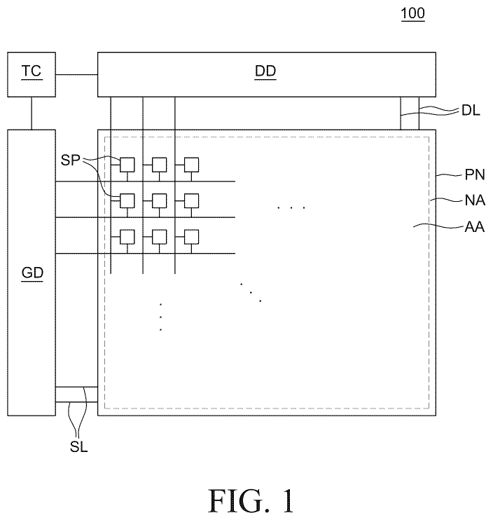

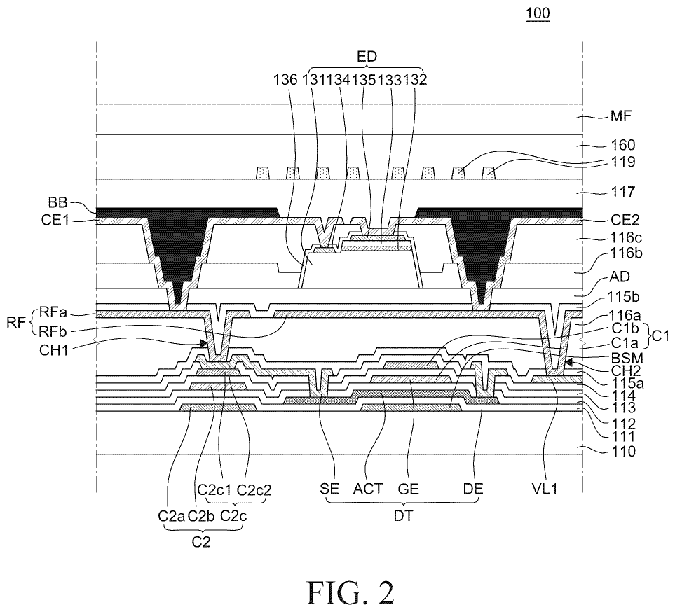

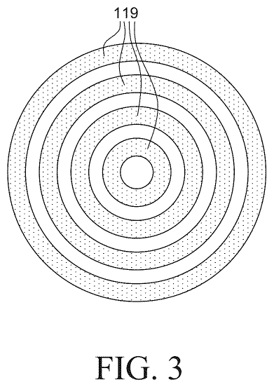

FIG. 1 is a schematic diagram of a display device according to an exemplary embodiment of the present disclosure. FIG. 2 is a cross-sectional view of a pixel area of a display device according to an exemplary embodiment of the present disclosure. FIG. 3 is a plan view of a plurality of patterns of a display device according to an exemplary embodiment of the present disclosure.

In FIG. 1, for the convenience of description, among various components of the display device 100, only a display panel PN, a gate driver GD, a data driver DD, and a timing controller TC are illustrated.

Referring to FIG. 1, the display device 100 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals supplied from the timing controller TC. Even though in FIG. 1, it is illustrated that one gate driver GD is disposed to be spaced apart from one side of the display panel PN, the number of the gate drivers GD and the placement thereof are not limited thereto.

The data driver DD converts image data input from the timing controller TC into a data voltage using a reference gamma voltage in accordance with a plurality of data control signals supplied from the timing controller TC. The data driver DD may supply the converted data voltage to the plurality of data lines DL.

The timing controller TC aligns image data input from the outside to supply the image data to the data driver DD. The timing controller TC may generate a gate control signal and a data control signal using synchronization signals input from the outside, such as a dot clock signal, a data enable signal, and horizontal/vertical synchronization signals. The timing controller TC supplies the generated gate control signal and data control signal to the gate driver GD and the data driver DD, respectively, to control the gate driver GD and the data driver DD.

The display panel PN is a configuration which displays images to the user and includes the plurality of sub pixels SP. In the display panel PN, the plurality of scan lines SL and the plurality of data lines DL intersect each other and the plurality of sub pixels SP is connected to the scan lines SL and the data lines DL, respectively. In addition, even though it is not illustrated in the drawing, each of the plurality of sub pixels SP is connected to a high potential power line, a low potential power line, and a reference line.

In the display panel PN, an active area AA and a non-active area NA enclosing the active area AA may be defined.

The active area AA is an area in which images are displayed in the display device 100. In the active area AA, a plurality of sub pixels SP which configures a plurality of pixels and a circuit for driving the plurality of sub pixels SP may be disposed. The plurality of sub pixels SP is a minimum unit which configures the active area AA and n sub pixels SP form one pixel. In each of the plurality of sub pixels SP, a light emitting diode and a thin film transistor for driving the light emitting diode may be disposed. The plurality of light emitting diodes may be defined in different manners depending on the type of the display panel PN. For example, when the display panel PN is an inorganic light emitting display panel, the light emitting diode may be a light emitting diode (LED) or a micro light emitting diode (micro-LED).

In the active area AA, a plurality of wiring lines which transmits various signals to the plurality of sub pixels SP is disposed. For example, the plurality of wiring lines includes a plurality of data lines DL which supplies a data voltage to each of the plurality of sub pixels SP and a plurality of scan lines SL which supplies a scan signal to each of the plurality of sub pixels SP. The plurality of scan lines SL extends to one direction in the active area AA to be connected to the plurality of sub pixels SP and the plurality of data lines DL extends to a direction different from the one direction in the active area AA to be connected to the plurality of sub pixels SP. In addition, in the active area AA, a low potential power line and a high potential power line may be further disposed but are not limited thereto.

The non-active area NA is an area where images are not displayed so that the non-active area NA may be defined as an area extending from the active area AA. In the non-active area NA, a link line which transmits a signal to the sub pixel SP of the active area AA, a pad electrode, or a driving IC, such as a gate driver IC or a data driver IC, may be disposed.

In the meantime, a driver, such as a gate driver GD, a data driver DD, and a timing controller TC, may be connected to the display panel PN in various ways. For example, the gate driver GD may be mounted in the non-active area NA in a gate in panel (GIP) manner or mounted between the plurality of sub pixels SP in the active area AA in a gate in active area (GIA) manner. For example, the data driver DD and the timing controller TC are formed in separate flexible film and printed circuit board PCB. The data driver DD and the timing controller TC are electrically connected to the display panel PN by bonding the flexible film and the printed circuit board PCB to the pad electrode formed in the non-active area NA of the display panel PN.

First, referring to FIG. 2, the display panel PN includes a substrate 110. The substrate 110 is a substrate which supports components disposed above the display device 100 and may be an insulating substrate. A plurality of pixels is formed on the substrate 110 to display images. For example, the substrate 110 may be formed by including glass or resin. Further, the substrate 110 may include polymer or plastic. In some exemplary embodiments, the substrate 110 may be formed of a plastic material having flexibility.

The plurality of sub pixels SP may be formed on the substrate 110 to form a plurality of rows and a plurality of columns. Each of the plurality of sub pixels SP includes a light emitting diode ED and a pixel circuit to independently emit light.

On the substrate 110, a plurality of wiring lines which supplies various signals to the plurality of sub pixels SP are disposed. For example, the plurality of data lines DL, the plurality of high potential power lines VL1, and the plurality of low potential power lines extending in the column direction may be disposed on the substrate 110. For example, a plurality of emission control signal lines, a plurality of auxiliary high potential power lines, a plurality of auxiliary low potential power lines, and a plurality of scan lines extending in the row direction may be disposed on the substrate 110. The high potential power line VL1 extending in the column direction may be electrically connected to the auxiliary high potential power line extending in the row direction through a contact hole. At this time, the emission control signal line transmits an emission control signal to the pixel circuits of the plurality of sub pixels SP to control emission timings of the plurality of sub pixels SP. However, the above-described type of the plurality of wiring lines is illustrative, but the type of the plurality of wiring lines to be actually used may be changed to various types according to the design.

The pixel circuit for driving the light emitting diode ED is disposed in each of the plurality of sub pixels SP on the substrate 110. The pixel circuit may include a plurality of thin film transistors and a plurality of capacitors. In FIG. 2, for the convenience of description, only a driving transistor DT, a first capacitor C1, and a second capacitor C2, among configurations of the pixel circuit are illustrated. However, the pixel circuit may further include a switching transistor, a sensing transistor, an emission control transistor, and the like but is not limited thereto.

On the substrate 110, a light shielding layer BSM, a driving transistor DT, a first capacitor C1, a second capacitor C2, a reflection plate RF, a plurality of light emitting diodes ED, a first connection electrode CE1, a second connection electrode CE2, a bank BB, a protection layer 117, a plurality of patterns 119, a cover layer 160, an optical film MF, and an insulating layer may be disposed. The insulating layer includes a plurality of inorganic insulating layers and a plurality of organic insulating layers.

Among the insulating layers disposed on the substrate 110, the plurality of inorganic insulating layers include a buffer layer 111, a gate insulating layer 112, a first interlayer insulating layer 113, a second interlayer insulating layer 114, a first passivation layer 115a, and a second passivation layer 115b.

Further, among the insulating layers disposed on the substrate 110, the plurality of organic insulating layers may include a first planarization layer 116a, an adhesive layer AD, a second planarization layer 116b, and a third planarization layer 116c.

Referring to FIG. 2, a light shielding layer BSM is disposed on the substrate 110. The light shielding layer BSM blocks light which is incident to active layers ACT of the plurality of transistors to minimize (or at least reduce) a leakage current. For example, the light shielding layer BSM is disposed below the active layer ACT of the driving transistor DT to block light incident onto the active layer ACT. If light is irradiated onto the active layer ACT, leakage current is generated, which deteriorates the reliability of the transistor. Accordingly, the light shielding layer BSM which blocks the light is disposed on the substrate 110 to improve the reliability of the driving transistor DT. The light shielding layer BSM may be configured by an opaque conductive material such as copper (Cu), aluminum (Al), molybdenum (Mo), nickel (Ni), titanium (Ti), chrome (Cr), or an alloy thereof but is not limited thereto.

The buffer layer 111 is disposed on the light shielding layer BSM. The buffer layer 111 is an inorganic insulating layer which reduces permeation of moisture or impurities through the substrate 110. For example, the buffer layer 111 may be configured by a single layer or a double layer of silicon oxide (SiOx) or silicon nitride (SiNx) but is not limited thereto. However, the buffer layer 111 may be omitted depending on a type of substrate 110 or a type of the thin film transistor but is not limited thereto.

A driving transistor DT including an active layer ACT, a gate electrode GE, a source electrode SE, and a drain electrode DE is disposed on the buffer layer 111.

Even though it is not illustrated in FIG. 2, an additional buffer layer may be also disposed between the substrate 110 and the light shielding layer BSM. The additional buffer layer is an inorganic insulating layer which reduces permeation of moisture or impurities through the substrate 110, like the above-described buffer layer 111, and for example, may be configured by a single layer or a double layer of silicon oxide (SiOx) or silicon nitride (SiNx) but is not limited thereto.

First, the active layer ACT of the driving transistor DT is disposed on the buffer layer 111. The active layer ACT may be formed of a semiconductor material, such as an oxide semiconductor, amorphous silicon, or polysilicon but is not limited thereto. Further, even though it is not illustrated in the drawings, other transistors, such as a switching transistor, a sensing transistor, and an emission control transistor, other than the driving transistor DT, may be further disposed. The active layers of the transistors are also formed of a semiconductor material, such as an oxide semiconductor, amorphous silicon, or polysilicon, but are not limited thereto. The active layer of the transistor included in the pixel circuit, such as the driving transistor DT, the switching transistor, the sensing transistor, and the emission control signal, may be formed of the same material, or formed of different materials.

The gate insulating layer 112 is disposed on the active layer ACT. The gate insulating layer 112 is an inorganic insulating layer which electrically insulates the active layer ACT from the gate electrode GE and may be configured by a single layer or a double layer of silicon oxide (SiOx) or silicon nitride (SiNx), but is not limited thereto.

The gate electrode GE is disposed on the gate insulating layer 112. The gate electrode GE may be configured by a conductive material, such as copper (Cu), aluminum (Al), molybdenum (Mo), nickel (Ni), titanium (Ti), chrome (Cr), or an alloy thereof, but is not limited thereto.

The first interlayer insulating layer 113 and the second interlayer insulating layer 114 are disposed on the gate electrode GE. In the first interlayer insulating layer 113 and the second interlayer insulating layer 114, contact holes through which the source electrode SE and the drain electrode DE are connected to the active layer ACT are formed. The first interlayer insulating layer 113 and the second interlayer insulating layer 114 are inorganic insulating layers which protect components therebelow and may be configured by single layers or double layers of silicon oxide (SiOx) or silicon nitride (SiNx), but are not limited thereto.

The source electrode SE and the drain electrode DE which are electrically connected to the active layer ACT are disposed on the second interlayer insulating layer 114. The source electrode SE is connected to the second capacitor C2 and the first electrode 134 of the light emitting diode ED and the drain electrode DE is connected to the other configuration of the pixel circuit. The source electrode SE and the drain electrode DE may be configured by a conductive material, such as copper (Cu), aluminum (Al), molybdenum (Mo), nickel (Ni), titanium (Ti), chrome (Cr), or an alloy thereof, but are not limited thereto.

The plurality of high potential power lines VL1 are disposed on the second interlayer insulting layer 114. The plurality of high potential power lines VL1 may transmit the high potential power voltage to the light emitting diode ED of each of the plurality of sub pixels SP. The plurality of high potential power lines VL1 may be configured by a conductive material such as copper (Cu), aluminum (Al), molybdenum (Mo), nickel (Ni), titanium (Ti), chrome (Cr), or an alloy thereof, but is not limited thereto.

Next, the first capacitor C1 is disposed on the gate insulating layer 112. The first capacitor C1 includes a 1-1-th capacitor electrode C1a and a 1-2-th capacitor electrode C1b.

First, the 1-1-th capacitor electrode C1a is disposed on the gate insulating layer 112. The 1-1-th capacitor electrode C1a is integrally formed with the gate electrode GE of the driving transistor DT.

The 1-2-th capacitor electrode C1b is disposed on the first interlayer insulating layer 113. The 1-2-th capacitor electrode C1b is disposed to overlap the 1-1-th capacitor electrode C1a with the first interlayer insulating layer 113 therebetween.

Therefore, the first capacitor C1 is connected to the gate electrode GE of the driving transistor DT to maintain a voltage of the gate electrode GE of the driving transistor DT for a predetermined period.

Next, the second capacitor electrode C2 is disposed on the substrate 110. The second capacitor C2 includes a 2-1-th capacitor electrode C2a, a 2-2-th capacitor electrode C2b, and a 2-3-th capacitor electrode C2c. The second capacitor C2 includes the 2-1-th capacitor electrode C2a which is a lower capacitor electrode, the 2-2-th capacitor electrode C2b which is an intermediate capacitor electrode, and the 2-3-th capacitor electrode C2c which is an upper capacitor electrode.

The 2-1-th capacitor electrode C2a is disposed on the substrate 110. The 2-1-th capacitor electrode C2a is disposed on the same layer as the light shielding layer BSM and is formed of the same material as the light shielding layer BSM.

The 2-2-th capacitor electrode C2b is disposed on the buffer layer 111 and the gate insulating layer 112. The 2-2-th capacitor electrode C2b is disposed on the same layer as the gate electrode GE and is formed of the same material as the gate electrode GE.

The 2-3-th capacitor electrode C2c is disposed on the first interlayer insulating layer 113. The 2-3-th capacitor electrode C2c is configured by a first layer C2c1 and a second layer C2c2. The first layer C2c1 of the 2-3-th capacitor electrode C2c is formed on the same layer as the 1-2-th capacitor electrode C1b with the same material as the 1-2-th capacitor electrode C1b. The first layer C2c1 is disposed so as to overlap the 2-1-th capacitor electrode C2a and the 2-2-th capacitor electrode C2b with the first interlayer insulating layer 113 therebetween.

The second layer C2c2 of the 2-3-th capacitor electrode C2c is disposed on the second interlayer insulating layer 114. The second layer C2c2 is a part extending from the source electrode SE of the driving transistor DT and is connected to the first layer C2c1 through the contact hole of the second interlayer insulating layer 114.

Accordingly, the second capacitor C2 is electrically connected between the source electrode SE of the driving transistor DT and the light emitting diode ED to increase capacitance inherent in the light emitting diode ED and allow the light emitting diode ED to emit light with a higher luminance.

The first passivation layer 115a is disposed on the driving transistor DT, the first capacitor C1, and the second capacitor C2. The first passivation layer 115a is an inorganic insulating layer which protects components below the first passivation layer 115a and may be configured by an inorganic material, such as silicon oxide (SiOx) or silicon nitride (SiNx) but is not limited thereto.

The first planarization layer 116a is disposed on the first passivation layer 115a. The first planarization layer 116a may planarize an upper portion of the pixel circuit including the driving transistor DT. The first planarization layer 116a may be configured by a single layer or a double layer, and for example, configured by benzocyclobutene or an acrylic organic insulating layer.

Referring to FIG. 2, the plurality of reflection plates RF are disposed on the first planarization layer 116a. The reflection plate RF has a configuration which reflects light emitted from the plurality of light emitting diodes ED above the substrate 110 and is formed in a shape corresponding to each of the plurality of sub pixels SP. One reflection plate RF is disposed to cover the most area of one sub pixel SP. The reflection plate RF reflects the light emitted from the light emitting diode ED and is also used as an electrode which electrically connects the light emitting diode ED and the pixel circuit. Therefore, the reflection plate RF may include various conductive layers in consideration of a light reflection efficiency and a resistance. For example, the reflection plate RF may use an opaque conductive layer, such as silver (Ag), aluminum (Al), molybdenum (Mo), titanium (Ti), or an alloy thereof and a transparent conductive layer, such as indium tin oxide (ITO), together, but the structure of the reflection plate RF is not limited thereto.

The reflection plate RF includes a plurality of first reflection plates RFa and a plurality of second reflection plates RFb disposed in each of the plurality of sub pixels SP.

The plurality of first reflection plates RFa reflect light emitted from the light emitting diode ED to the outside of the display device 100. The plurality of first reflection plates RFa are disposed in the driving transistor DT in each of the plurality of sub pixels SP to be electrically connected to the source electrode SE of the driving transistor DT and the second capacitor C2 through a first contact hole CH1.

The plurality of second reflection plates RFb may be disposed so as to overlap the light emitting diode ED. The plurality of second reflection plates RFb are disposed in the driving transistor DT in each of the plurality of sub pixels SP to be electrically connected to the high potential power line VL1 through a second contact hole CH2. Therefore, the plurality of second reflection plates RFb reflect the light emitted from the light emitting diode ED to the outside of the display device 100 while supplying the high potential power voltage to the light emitting diode ED.

In the meantime, all the plurality of light emitting diodes ED may be separately connected to the high potential power line VL1, without being connected to the reflection plate RF, but is not limited thereto.

Referring to FIG. 2, the second passivation layer 115b is disposed on the plurality of reflection plates RF. The second passivation layer 115b is an inorganic insulating layer which protects components below the second passivation layer 115b and may be configured by a single layer or a double layer of silicon oxide (SiOx) or silicon nitride (SiNx) but is not limited thereto.

The adhesive layer AD is disposed on the second passivation layer 115b. The adhesive layer AD is formed on the front surface of the substrate 110 to fix the light emitting diode ED disposed on the adhesive layer AD. The adhesive layer AD is formed of an organic insulating layer. The adhesive layer AD may be formed of a photo curable adhesive material which is cured by light. For example, the adhesive layer AD may be formed of an acrylic material including a photoresist, but is not limited thereto.

The plurality of light emitting diodes ED are disposed in each of the plurality of sub pixels SP on the adhesive layer AD. The light emitting diode ED is an element which emits light by a current and includes a first light emitting diode which emits red light, a second light emitting diode which emits green light, and a third light emitting diode which emits blue light and implements light with various colors including white by a combination thereof. For example, the light emitting diode ED may be a light emitting diode (LED) or a micro LED, but is not limited thereto.

The plurality of light emitting diodes ED include a first semiconductor layer 131, an active layer 132, a second semiconductor layer 133, a first electrode 134, and a second electrode 135.

The plurality of light emitting diodes ED may be formed in various structures such as a lateral structure, vertical structure, or a flip chip structure. The lateral light emitting diode includes a first electrode and a second electrode which are disposed horizontally on both sides of the active layer. The vertical light emitting diode includes a first electrode and a second electrode which are disposed on and below the active layer. The flip chip light emitting diode has the substantially same structure as the lateral light emitting diode. However, in the lateral light emitting diode, the first electrode and the second electrode are horizontally disposed above the active layer, but in the flip chip light emitting diode, the first electrode and the second electrode are horizontally disposed below the active layer. Hereinafter, it is assumed that the plurality of light emitting diodes ED has a lateral structure, but the type of the plurality of light emitting diodes ED is not limited thereto.

The first semiconductor layer 131 is disposed on the adhesive layer AD and the second semiconductor layer 133 is disposed on the first semiconductor layer 131. The first semiconductor layer 131 and the second semiconductor layer 133 may be layers formed by doping n-type and p-type impurities into a specific material. For example, the first semiconductor layer 131 and the second semiconductor layer 133 may be layers doped with n-type and p-type impurities into a material such as gallium nitride (GaN), indium aluminum phosphide (InAIP), or gallium arsenide (GaAs). The p-type impurity may be magnesium (Mg), zinc (Zn), and beryllium (Be), and the n-type impurity may be silicon (Si), germanium, and tin (Sn), but is not limited thereto.

The active layer 132 is disposed between the first semiconductor layer 131 and the second semiconductor layer 133. The active layer 132 is supplied with holes and electrons from the first semiconductor layer 131 and the second semiconductor layer 133 to emit light. The active layer 132 may be formed by a single layer or a multi-quantum well (MQW) structure, and for example, may be formed of indium gallium nitride (InGaN) or gallium nitride (GaN), but is not limited thereto.

In the meantime, a part of the first semiconductor layer 131 outwardly protrudes from the second semiconductor layer 133 and the active layer 132 to be exposed from the second semiconductor layer 133 and the active layer 132.

The first semiconductor layer 131 is configured to enclose the active layer 132 and the second semiconductor layer 133 on the plane. That is, all the active layer 132 and the second semiconductor layer 133 may be disposed so as to overlap the first semiconductor layer 131 and only a part of the inner part of the first semiconductor layer 131 overlaps the active layer 132 and the second semiconductor layer 133.

At this time, the second semiconductor layer 133 and the active layer 132 which protrude from the first semiconductor layer 131 are referred to as a mesa portion. A side surface of the mesa portion, that is, a side surface of the semiconductor layer 133 and a side surface of the active layer 132 are disposed to be inclined with a bottom surface of the first semiconductor layer 131.

The first electrode 134 is disposed on the first semiconductor layer 131. The first electrode 134 is an electrode which electrically connects the driving transistor DT and the first semiconductor layer 131. In this case, the first semiconductor layer 131 is a semiconductor layer doped with an n-type impurity and the first electrode 134 may be a cathode. The first electrode 134 may be disposed on a top surface of the first semiconductor layer 131 which is exposed from the active layer 132 and the second semiconductor layer 133. The first electrode 134 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 135 is disposed on the second semiconductor layer 133. The second electrode 135 is disposed on the top surface of the second semiconductor layer 133. The second electrode 135 is an electrode which electrically connects the high potential power line VL1 and the second semiconductor layer 133. In this case, the second semiconductor layer 133 is a semiconductor layer doped with a p-type impurity and the second electrode 135 may be an anode. The second electrode 135 may be configured by a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

Next, an encapsulation layer 136 which encloses the first semiconductor layer 131, the active layer 132, the second semiconductor layer 133, the first electrode 134, and the second electrode 135 is disposed. The encapsulation layer 136 is formed of an insulating material to protect the first semiconductor layer 131, the active layer 132, and the second semiconductor layer 133. In the encapsulation layer 136, contact holes which exposes the first electrode 134 and the second electrode 135 are formed to electrically connect a first connection electrode CE1 and a second connection layer CE2 to the first electrode 134 and the second electrode 135.

In the meantime, a part of the side surface of the first semiconductor layer 131 may be exposed from the encapsulation layer 136. The light emitting diode ED manufactured on the wafer is separated from the wafer to be transferred onto the display panel PN. However, during the process of separating the light emitting diode ED from the wafer, a part of the encapsulation layer 136 may be torn. For example, a part of the encapsulation layer 136 which is adjacent to a lower edge of the first semiconductor layer 131 of the light emitting diode ED is torn during the process of separating the light emitting diode ED from the wafer. Accordingly, a part of a lower side surface of the first semiconductor layer 131 may be exposed to the outside. However, even though the lower portion of the light emitting diode ED is exposed from the encapsulation layer 136, the first connection electrode CE1 and the second connection electrode CE2 are formed after forming the second planarization layer 116b and the third planarization layer 116c which cover the side surface of the first semiconductor layer 131. Accordingly, a short defect may be reduced.

Next, the second planarization layer 116b and the third planarization layer 116c are disposed on the adhesive layer AD and the light emitting diode ED.

The second planarization layer 116b overlaps a part of side surfaces of the plurality of light emitting diodes ED to fix and protect the plurality of light emitting diodes ED. The second planarization layer 116b may be configured by a single layer or a double layer, and for example, configured by benzocyclobutene or an acrylic organic insulating layer. The second planarization layer 116b may be formed using a halftone mask. Therefore, the second planarization layer 116b is formed to have a step.

Specifically, a part of the second planarization layer 116b which is relatively adjacent to the light emitting diode ED is formed to have a smaller thickness and a part which is farther from the light emitting diode ED is formed to have a larger thickness. A part of the second planarization layer 116b which is adjacent to the light emitting diode ED is disposed to enclose the light emitting diode ED and also is in contact with a side surface of the light emitting diode ED. Therefore, a torn part of the encapsulation layer 136 which protects a side surface of the first semiconductor layer 131 of the light emitting diode ED during the process of separating the light emitting diode ED from the wafer to be transferred onto the display panel PN is covered by the second planarization layer 116b. By doing this, contacts and short defects of the first connection electrode CE1 and the second connection electrode CE2 and the first semiconductor layer 131 may be suppressed thereafter.

The third planarization layer 116c is formed to cover upper portions of the second planarization layer 116b and the light emitting diode ED and contact holes which expose the first electrode 134 and the second electrode 135 of the light emitting diode ED may be formed. The first electrode 134 and the second electrode 135 of the light emitting diode ED are exposed from the third planarization layer 116c and the third planarization layer 116c is partially disposed in an area between the first electrode 134 and the second electrode 135 to reduce a short defect. The second planarization layer 116b and the third planarization layer 116c may be configured by a single layer or a double layer, and for example, may be formed of photoresist or an acrylic organic insulating material.

In the meantime, the third planarization layer 116c may cover the light emitting diode ED and an area adjacent to the light emitting diode ED. The third planarization layer 116c is disposed in an area of the sub pixel SP enclosed by the bank BB and is disposed in an island shape. Therefore, a bank BB is disposed on a part of the top surface of the second planarization layer 116b. For example, the bank BB is disposed on the third planarization layer 116c so as to overlap a part of the third planarization layer 116c.

The first connection electrode CE1 and the second connection electrode CE2 are disposed on the third planarization layer 116c.

The first connection electrode CE1 is an electrode which electrically connects the first electrode 134 of the light emitting diode ED and the driving transistor DT. The first connection electrode CE1 is electrically connected to the first electrode 134 exposed from the third planarization layer 116c and is electrically connected to the first reflection plate RFa through a contact hole formed in the third planarization layer 116c, the second planarization layer 116b, the adhesive layer AD, and the second passivation layer 115b, simultaneously. Therefore, the first electrode 134 and the source electrode SE of the driving transistor DT are electrically connected by means of the first connection electrode CE1 and the first reflection plate RFa.

The second connection electrode CE2 is an electrode which electrically connects the second electrode 135 of the light emitting diode ED and the high potential power line VL1. The second connection electrode CE2 is electrically connected to the second electrode 135 exposed from the third planarization layer 116c and is electrically connected to the second reflection plate RFb through a contact hole formed in the third planarization layer 116c, the second planarization layer 116b, the adhesive layer AD, and the second passivation layer 115b. Accordingly, the second electrode 135 and the high potential power line VL1 are electrically connected through the second connection electrode CE2.

The first connection electrode CE1 and the second electrode CE2 are formed of a transparent conductive material, such as indium tin oxide (ITO) or indium zinc oxide (IZO), but are not limited thereto.

In the meantime, in the drawing, it is illustrated that the first electrode 134, the first connection electrode CE1, and the first reflection plate RFa are electrically connected to the source electrode SE of the driving transistor DT. However, the first electrode 134, the first connection electrode CE1, and the first reflection plate RFa may be connected to the drain electrode DE of the driving transistor DT, but it is not limited thereto.

Referring to FIG. 2, the bank BB is disposed on the second planarization layer 116b exposed from the first connection electrode CE1 and the second connection electrode CE2, and the third planarization layer 116c. The bank BB is disposed to be spaced apart from the light emitting diode ED with a predetermined interval and overlaps at least partially the reflection plate RF. For example, the bank BB may cover a part of the first connection electrode CE1 and the second connection electrode CE2 formed in the contact holes of the third planarization layer 116c and the second planarization layer 116b. Further, the bank BB may be disposed on the second planarization layer 116b with a predetermined interval from the light emitting diode ED.

The bank BB may be formed of an opaque material to reduce color mixture between the plurality of sub pixels SP and for example, may be formed of black resin, but is not limited thereto.

In the meantime, a thickness of a part of the bank BB which is formed in the contact holes of the third planarization layer 116c and the second planarization layer 116b that covers a part of the first connection electrode CE1 and the second connection electrode CE2 and a thickness of a part disposed on the second planarization layer 116b may be different from each other. Specifically, when the part of the bank BB covers a part of the first connection electrode CE1 and the second connection electrode CE2 formed in the contact holes of the third planarization layer 116c and the second planarization layer 116b, since the contact holes are formed from the second passivation layer 115b to the third planarization layer 116c, the bank BB may be disposed below the light emitting diode ED, that is, disposed to be lower than the light emitting diode ED. Therefore, the thickness of the part of the bank BB which covers a part of the first connection electrode CE1 and the second connection electrode CE2 formed in the contact holes of the third planarization layer 116c and the second planarization layer 116b may be larger than the thickness of a part of the bank BB disposed on the second planarization layer 116b.

However, it is not limited thereto and the bank BB may be disposed at the outside of the contact holes of the third planarization layer 116c and the second planarization layer 116b to cover a part of the first connection electrode CE1 and the second connection electrode CE2.

The protection layer 117 is disposed on the first connection electrode CE1, the second connection electrode CE2, and the bank BB. The protection layer 117 is a layer for protecting configurations below the protection layer 117. The protection layer 117 may be configured by a single layer or a double layer, and for example, configured by benzocyclobutene, a light-transmitting epoxy, a photoresist, or an acrylic organic material, but is not limited thereto.

A plurality of ring-shaped patterns 119 are disposed on the protection layer 117. The plurality of patterns 119 are disposed so as to correspond to the plurality of light emitting diodes ED.

At this time, referring to FIG. 3, the plurality of patterns 119 may have a concentric shape and spaced distances between the plurality of patterns 119 may be the same. At this time, the plurality of patterns 119 may not be disposed in an area corresponding to a center portion of the light emitting diode ED. For example, an innermost pattern, among the plurality of patterns, may be disposed to enclose a circle having a diameter of 6 μm to 8 μm.

In the meantime, a sum of a width of one pattern 119, among the plurality of patterns 119, and the spaced distance between the plurality of patterns may be equal to or smaller than 10 μm. At this time, in consideration of the spaced distance between the plurality of patterns 119 and the width of the plurality of patterns 119, at least three patterns 119 may be disposed on the light emitting diode ED, but is not limited hereto. Further, a width of a top surface of the plurality of patterns 119 may be 3 μm.

The plurality of patterns 119 may be formed of a material having a refractive index lower than that of the cover layer 160. For example, the plurality of patterns 119 may be formed of a photoresist or an acrylic organic material, but is not limited thereto.

The plurality of patterns 119 are disposed so as to overlap the plurality of light emitting diodes ED disposed therebelow.

At this time, a diameter of an outermost pattern 119, among the plurality of patterns 119, may be twice or more the diameter of the light emitting diode ED. Therefore, the plurality of patterns 119 may extract light traveling in a lateral direction of the light emitting diode ED in a front direction. For example, the luminance of the light emitting diode ED may be high on a side surface of 50 to 70 degrees from the front surface. At this time, when the size of the light emitting diode ED is 10 μm to 30 μm and the light emitting diode ED and the plurality of patterns 119 are spaced apart from each other with an interval of 3 μm to 6 μm, the plurality of patterns 119 is disposed in an area corresponding to twice the diameter of the light emitting diode ED. Therefore, the light traveling in the lateral direction of the light emitting diode ED may be covered.

The plurality of patterns 119 may include bottom surfaces and inclined side surfaces of the plurality of patterns 119. For example, an inclined angle formed by the side surfaces of the plurality of patterns 119 and the bottom surfaces of the plurality of patterns 119 may be 55 degrees or larger and the inclined side surfaces of the plurality of patterns 119 may change the path of light which travels in the lateral direction of the light emitting diode ED.

A cover layer 160 is disposed above the plurality of patterns 119 and the protection layer 117.

The cover layer 160 may be disposed so as to cover the plurality of patterns 119 and may be formed of a material having a refractive index higher than a refractive index of the plurality of patterns 119. For example, the cover layer 160 may be formed of a material including parylene, but is not limited thereto.

Referring to FIG. 2, an optical film MF which covers an upper portion of the cover layer 160 is disposed in the entire upper area of the substrate 110. The optical film MF is disposed on a seal member and the protection layer 117. The optical film MF may be a functional film which implements a higher quality of images while protecting the display device 100. For example, the optical film MF may include an anti-scattering film, an anti-glare film, an anti-reflecting film, a low-reflecting film, an OLED transmittance controllable film, or a polarizer, but is not limited thereto.

In the meantime, an adhering unit is disposed between the protection layer 117 and the optical film MF above the substrate 110. The adhering unit is formed on the front surface of the substrate 110 to bond between the protection layer 117 and the optical film MF. The adhering unit may be formed of a photo curable adhesive material which is cured by light. For example, the adhering unit may be formed of an acrylic material including a photoresist, but is not limited thereto.

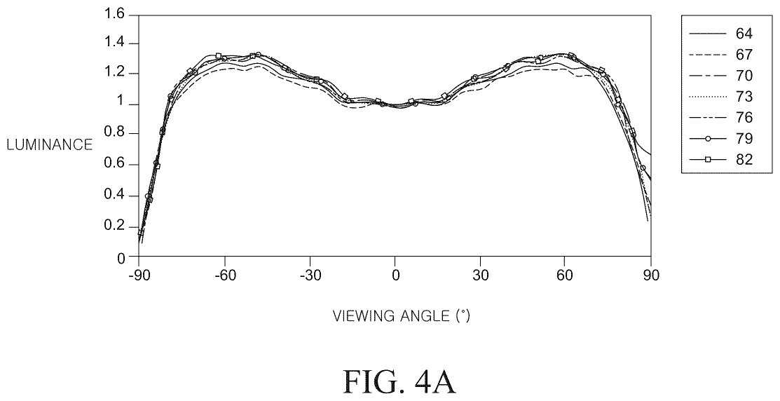

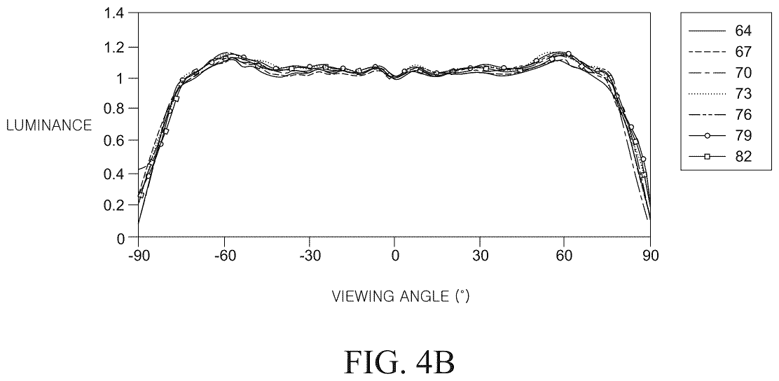

FIGS. 4A and 4B are graphs for explaining an effect of a display device according to an exemplary embodiment of the present disclosure. FIG. 4A is a graph for explaining a luminance distribution of a display device according to a comparative example and FIG. 4B is a graph for explaining a luminance distribution of a display device 100 according to an example of the present disclosure. In the display device according to the comparative example, a plurality of patterns 119 and the cover layer 160 are not disposed, which is different from the display device 100 according to an example of the present disclosure.

FIGS. 4A and 4B illustrate a luminance distribution according to a viewing angle measured in the comparative example and the example and illustrate the luminance distribution according to the viewing angle when an inclination angle of the mesa unit is changed to 64°, 67° 70°, 73°, 76°, 79°, and 82° in the comparative example and the example. On the graphs of FIGS. 4A and 4B, an X-axis indicates a viewing angle. On the graphs of FIGS. 4A and 4B, the Y-axis indicates a luminance and the luminance in a front direction is set to be 1.

Referring to FIGS. 4A and 4B, in the comparative example and the example, the luminance is higher in the lateral direction of 50° to 70° than in the front direction and is maximum at approximately 60°. At this time, referring to FIG. 4A, in the comparative example, a maximum luminance is approximately 1.2 to 1.4. Referring to FIG. 4B, in the example, a maximum luminance is approximately 1.0 to 1.2 so that it is confirmed that the luminance deviation is reduced as compared with the comparative example.

The result according to the graphs of FIGS. 4A and 4B are summarized in the following Table 1.

TABLE 1

| | Front | Viewing angle | Viewing angle |
|---|---|---|---|
| | luminance | luminance deviation | luminance ratio |
| Comparative | 100% | 8% | 1.34 |
| Example | | | |
| Example | 113% | 5.1% | 1.12 |

A viewing angle luminance deviation refers to a deviation between maximum luminance measured in each condition when the inclination angle of the mesa unit is 64°, 67°, 70°, 73°, 76°, 79°, and 82°.

The front luminance is a luminance at a viewing angle of 0° when the inclination angle of the mesa unit is 67° and is the luminance when the front luminance is 100% in the comparative example.

A viewing angle luminance ratio is a ratio of the maximum luminance measured in the lateral direction to the front luminance when the inclination angle of the mesa unit is 67°.

Referring to FIGS. 4A and 4B, and Table 1, when the front luminance in the comparative example is 100%, the front luminance in the example is approximately 113%. At this time, it is confirmed that as compared with the comparative example in which the plurality of patterns 119 is not disposed, in the example in which the plurality of patterns 119 is disposed, the front luminance is improved by approximately 13%.

Further, referring to FIGS. 4A and 4B, and Table 1, when the viewing angle luminance deviation in the comparative example is 8%, the viewing angle luminance deviation in the example is approximately 5.1%. That is, it is confirmed that as compared with the comparative example in which the plurality of patterns 119 is not disposed, in the example in which the plurality of patterns 119 is disposed, the viewing angle luminance deviation is reduced by approximately 2.9%.

Further, referring to FIGS. 4A and 4B, and Table 1, the viewing angle luminance ratio in the comparative example is 1.34 and the viewing angle luminance ratio in the example is 1.12. It is confirmed that as compared with the comparative example in which the plurality of patterns 119 is not disposed, in the example in which the plurality of patterns 119 is disposed, the viewing angle luminance ratio deviation is reduced by approximately 0.22.

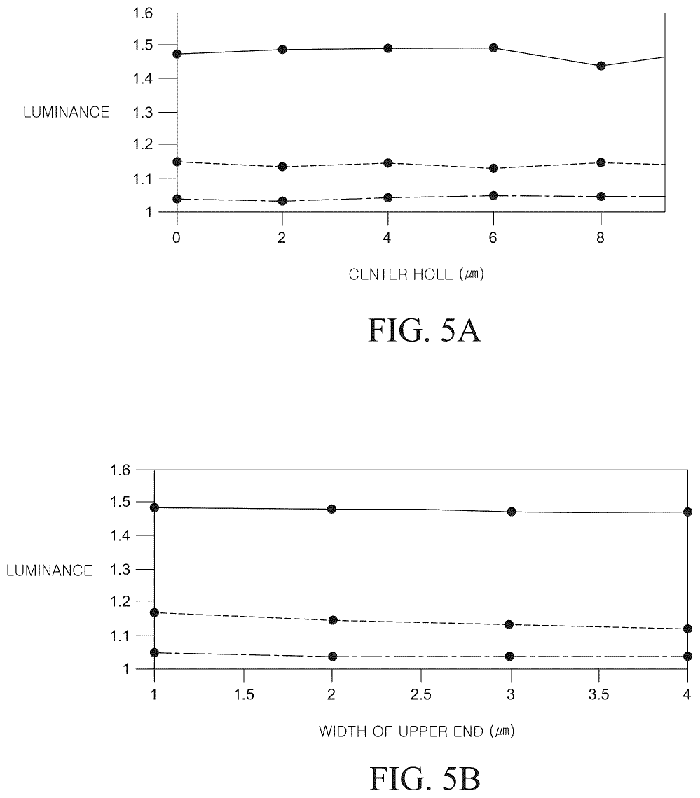

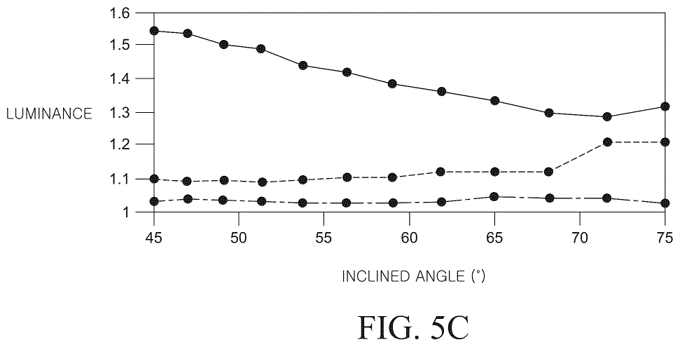

FIGS. 5A to 5C are graphs for explaining an effect of a display device according to an exemplary embodiment of the present disclosure. In the graph of FIG. 5A, the X-axis indicates a size of a center hole of the plurality of patterns 119 and it means an inner diameter of a pattern 119 disposed at the center of the plurality of patterns 119. In the graph of FIG. 5B, the X-axis indicates a width of an upper end of the plurality of patterns 119. In the graph of FIG. 5C, the X-axis indicates an inclination angle of the plurality of patterns 119. In the graphs of FIGS. 5A to 5C, the Y axis indicates a luminance.

In the graphs illustrated in FIGS. 5A to 5C, a total amount of light, a front luminance, and a luminance uniformity of the example when a center hole size of the plurality of patterns 119, a width of the upper end of the plurality of patterns 119, and an inclination angle of the plurality of patterns 119 are changed are illustrated, In FIGS. 5A to 5C, a total amount of light indicates a total amount of light of the example when a total amount of light extracted in the comparative example is 1. The front luminance means a ratio of a front luminance of the example when the front luminance of the comparative example is 1. Further, the luminance uniformity means a deviation between the front luminance and the maximum luminance in the lateral direction.

Referring to FIG. 5A, when the center hole size of the plurality of patterns 119 is changed from 0 μm to 10 μm, the highest luminance of approximately 1.15 is obtained with the center hole size of the plurality of patterns 119 of 0 μm. Further, when the center hole size of the plurality of patterns 119 is 6 μm, a highest total amount of light of approximately 1.05 is obtained and when the center hole size of the plurality of patterns 119 is 8 μm, the luminance uniformity with a smallest deviation of approximately 1.45 is obtained.

Referring to FIG. 5B, when the width of the upper end of the plurality of patterns 119 is changed from 1 μm to 4 μm, the smaller the width of the upper end of the plurality of patterns 119, the larger the front luminance and the total amount of light. When the width of upper end of the plurality of patterns 119 is 1 μm, the front luminance is approximately 1.17 and the total amount of light is approximately 1.05. When the center hole size of the plurality of patterns 119 is 3 μm, the luminance uniformity with a smallest deviation of approximately 1.47 is obtained.

Referring to FIG. 5C, when the inclination angle of the plurality of patterns 119 is changed from 45 degrees to 75 degrees, the highest front luminance of approximately 1.25 is obtained at the inclination angle of the plurality of patterns 119 of 71 degrees. Further, the highest total amount of light of approximately 1.05 is obtained at the inclination angle of the plurality of patterns 119 of 65 degrees. However, when the inclination angle of the plurality of patterns 119 is 55 degrees or smaller, the luminance uniformity is higher than approximately 1.5 which is the luminance uniformity of the comparative example. Therefore, it is confirmed that the luminance deviation according to the viewing angle is increased as compared with the comparative example.

In display device, the luminance deviation occurs depending on the viewing angle according to the shape of the light emitting diode and component tolerances. When the micro light emitting diode (micro-LED) is used as the light emitting diode, the lateral luminance, that is, the luminance in the direction of 50 degrees to 70 degrees is increased more than the front luminance and the maximum luminance is obtained in the approximately 60 degree-direction. Therefore, the luminance distribution graph according to the viewing angle may be shown as an M shape, which may cause the mura phenomenon.

Further, in the case of the micro-LED, the luminance distribution according to the viewing angle may vary according to an inclination angle of an area referred to as a mesa unit of the light emitting diode, that is, the side surfaces of the second semiconductor layer 133 and the active layer 132. In the meantime, as the light emitting diode is manufactured to have a small size, the shape and the inclination angle of the mesa unit may be affected even by small tolerance error. For example, when the light emitting diode is manufactured to have a size of approximately 30 μm, a deviation in the inclination angle of the mesa portion may occur even with a tolerance at the μm level. Therefore, it is difficult to control the viewing angle deviation according to the tolerance effort.

Therefore, in the display device 100 according to the exemplary embodiment of the present disclosure, a plurality of ring-shaped patterns 119 which is formed of a low refractive material is disposed below the cover layer 160 which is formed of a high refractive material to cover the light which is laterally emitted to be extracted in the front direction. Further, the plurality of concentric patterns 119 are disposed so as to correspond to a size of the light emitting diode ED to cover the luminance deviation of the light emitting diode ED caused by the transferring error. Accordingly, in the display device 100 according to the exemplary embodiment of the present disclosure, light which laterally travels is extracted in the front direction to reduce the viewing angle deviation and achieve high color reproducibility. Further, the front luminance of the display device 100 is increased to provide a display device 100 with a high luminance and a high efficiency and improve the mura phenomenon.

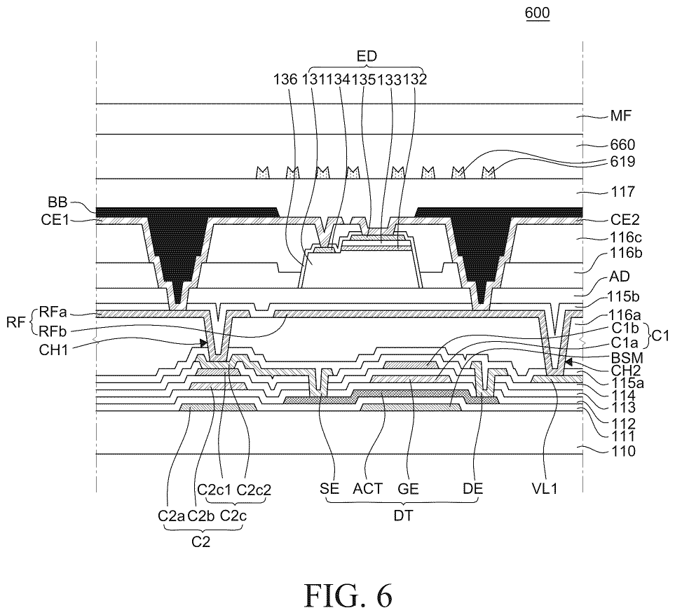

FIG. 6 is a cross-sectional view of a pixel area of a display device according to another exemplary embodiment of the present disclosure. The only difference between a display device 600 of FIG. 6 and the display device 100 of FIGS. 1 to 3B is a plurality of patterns 619, but the other configurations are substantially the same, so that a redundant description will be omitted.

Referring to FIG. 6, a plurality of ring-shaped patterns 619 are disposed on the protection layer 117. The plurality of patterns 619 may be recessed toward the substrate 110. For example, each pattern 619 has a smallest height at the center and has a largest height in the lateral direction. At this time, a top surface of each pattern 619 is disposed to have a predetermined inclination angle with respect to the bottom surface of the pattern 619. For example, as illustrated in FIG. 6, the top surface of each pattern 619 may be formed by two planes which are symmetrically disposed with respect to the center of the pattern 619.

A cover layer 660 is disposed above the plurality of patterns 619 and the protection layer 117 to cover top surfaces and side surfaces of the plurality of patterns 619.

In the display device 600 according to another exemplary embodiment of the present disclosure, a plurality of ring-shaped patterns 619 formed of a low refractive material are disposed below the cover layer 660 formed of a high refractive material to extract light which laterally travels in the front direction. Further, a display device 600 with a high color reproducibility, high luminance, and high efficiency may be implemented.

In the display device 600 according to another exemplary embodiment of the present disclosure, the top surfaces of the plurality of patterns 619 are recessed toward the substrate 110. For example, the top surfaces of the plurality of patterns 619 may be formed by inclined planes with respect to the bottom surfaces of the plurality of patterns 619. Therefore, light which is laterally incident onto the top surfaces of the plurality of patterns 619 travels in the front direction while passing through the inclined top surfaces of the plurality of patterns 619. Accordingly, in the display device 600 according to another exemplary embodiment of the present disclosure, the front luminance is improved so that the display device 600 with a high luminance and a high efficiency may be implemented.

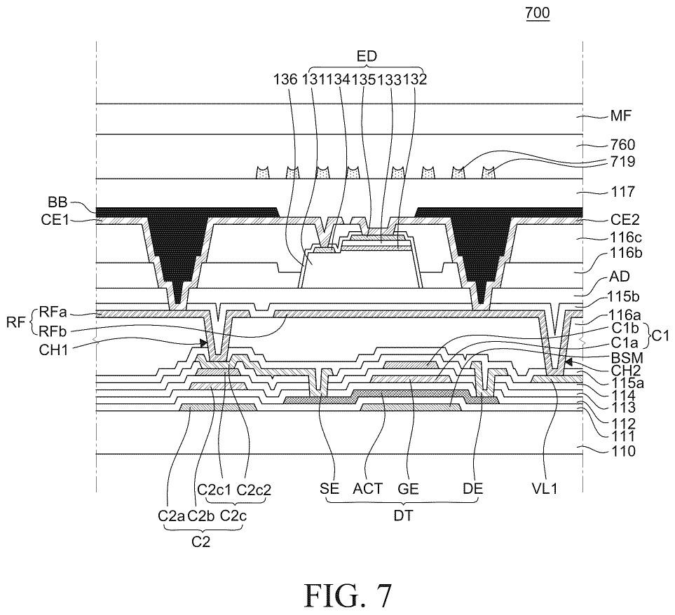

FIG. 7 is a cross-sectional view of a pixel area of a display device according to still another exemplary embodiment of the present disclosure. The only difference between a display device 700 of FIG. 7 and the display device 100 of FIGS. 1 to 3B is a plurality of patterns 719, but the other configurations are substantially the same, so that a redundant description will be omitted.

Referring to FIG. 7, a plurality of ring-shaped patterns 719 are disposed on the protection layer 117. The plurality of patterns 719 may be recessed toward the substrate 110. Therefore, each pattern 719 has a smallest height at the center and has a largest height in the lateral direction. For example, the top surfaces of the plurality of patterns 719 be curved surface recessed toward the substrate 110. Therefore, an inclination angle formed by the top surface and the bottom surface of each pattern 719 may vary depending on the position and for example, the inclination angle of the top surface of the pattern 719 may increase as it moves away from the center of each pattern 719.

A cover layer 760 is disposed above the plurality of patterns 719 and the protection layer 117 to cover top surfaces and side surfaces of the plurality of patterns 719.

In the display device 700 according to another exemplary embodiment of the present disclosure, a plurality of ring-shaped patterns 719 formed of a low refractive material are disposed below the cover layer 760 formed of a high refractive material to extract light which laterally travels in the front direction. Further, a display device 700 with a high color reproducibility, high luminance, and high efficiency may be implemented.

In the display device 700 according to still another exemplary embodiment of the present disclosure, the top surfaces of the plurality of patterns 719 are recessed toward the substrate 110. For example, the top surfaces of the plurality of patterns 719 may be formed by curved surfaces recessed toward the bottom surfaces of the plurality of patterns 719. Therefore, the inclination angle formed by the top surfaces and the bottom surfaces of the plurality of patterns 719 may vary in every position. Accordingly, the viewing angle luminance distribution of the display device 700 may be controlled according to the inclination angle formed by the top surfaces of the plurality of patterns 719. Accordingly, in the display device 700 according to another exemplary embodiment of the present disclosure, the top surfaces of the plurality of patterns 719 are disposed to have a curved shape to adjust the viewing angle luminance distribution of the display device 700.

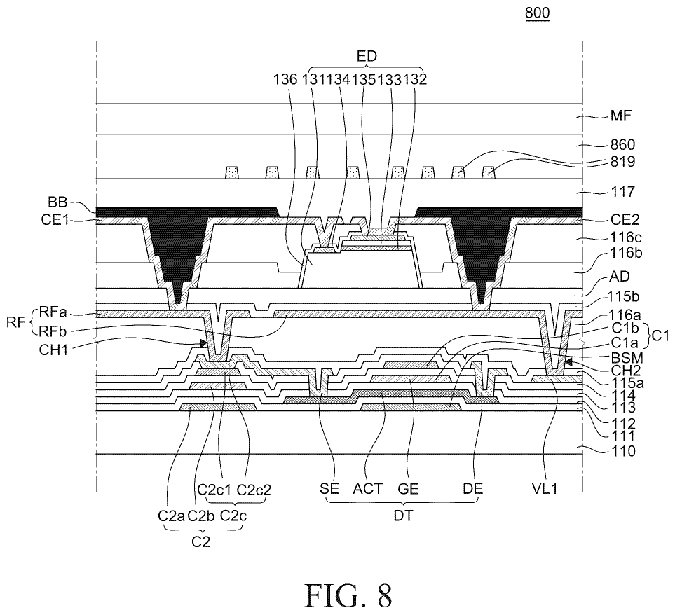

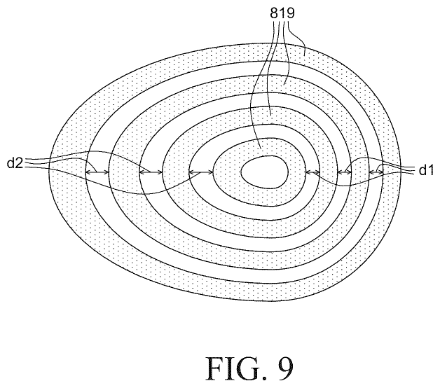

FIG. 8 is a cross-sectional view of a pixel area of a display device according to still another exemplary embodiment of the present disclosure. FIG. 9 is a plan view of a plurality of patterns of a display device according to still another exemplary embodiment of the present disclosure. FIG. 9 is a plan view of the plurality of patterns 819 of FIG. 8. The only difference between the display device 800 of FIG. 8 and the display device 100 of FIGS. 1 to 3B is a plurality of patterns 819, but the other configurations are substantially the same, so that a redundant description will be omitted.

Referring to FIG. 8, a plurality of ring-shaped patterns 819 are disposed on the protection layer 117.

A spaced distance between the plurality of patterns 819 disposed on one side from a center of the light emitting diode ED and a spaced distance between the plurality of patterns 819 disposed on the other side from the center of the light emitting diode ED may be different. For example, as illustrated in FIG. 8, a second electrode 135 of the light emitting diode ED is disposed at one side of the light emitting diode ED and a first electrode 134 of the light emitting diode ED is disposed at the other side of the light emitting diode ED. At this time, the spaced distance between the plurality of patterns 819 disposed on one side from the center of the light emitting diode ED is smaller than the spaced distance between the plurality of patterns 819 disposed on the other side from the center of the light emitting diode ED.

Referring to FIG. 9, a first interval d1 which is the spaced distance between the plurality of patterns 819 disposed on one side from the center of the light emitting diode ED is smaller than a second interval d2 which is the spaced distance between the plurality of patterns 819 disposed on the other side from the center of the light emitting diode ED. Therefore, the plurality of patterns 819 is disposed to be asymmetrical with respect to the center and is asymmetrical to the center of the light emitting diode ED.

In the meantime, the light emitting diode ED has different luminance distributions according to the viewing angle and the plurality of patterns 819 is disposed so as to correspond to the luminance distribution of the light emitting diode ED. For example, the maximum luminance at one side of the light emitting diode ED is higher than the maximum luminance at the other side of the light emitting diode ED. The spaced distance between the plurality of patterns 819 disposed on one side of the light emitting diode ED may be smaller than the spaced distance between the plurality of patterns 819 disposed on the other side of the light emitting diode ED.

A cover layer 860 is disposed above the plurality of patterns 819 and the protection layer 117 to cover top surfaces and side surfaces of the plurality of patterns 819.

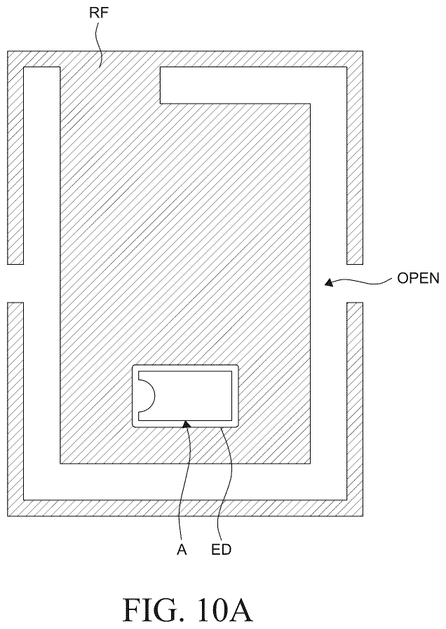

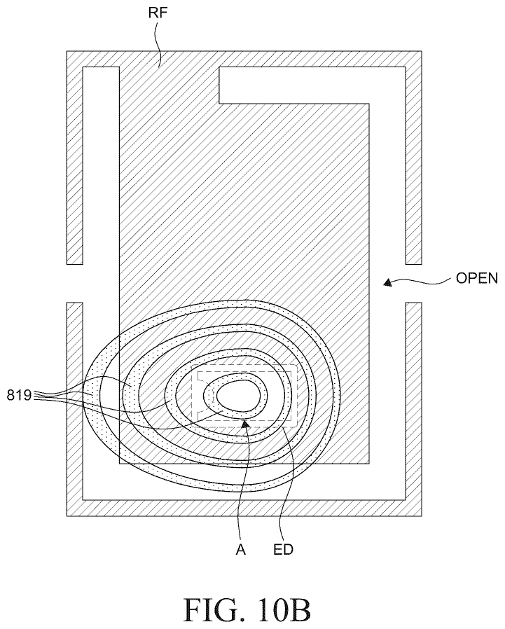

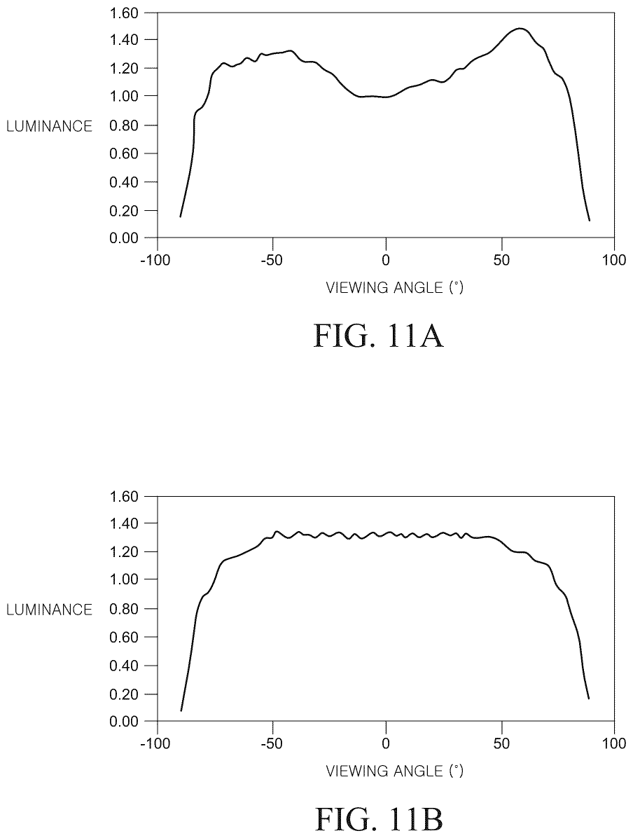

Hereinafter, the luminance distribution of the light emitting diode ED and the spaced distance between a plurality of patterns 819 will be described with reference to FIGS. 10A to 11B together.

FIGS. 10A and 10B are schematic plan views of a display device according to still another exemplary embodiment of the present disclosure. FIGS. 10A and 10B are plan views of a display device 800 of FIG. 8 and in FIGS. 10A and 10B, for the convenience of illustration, only a reflection plate RF, a light emitting diode ED, an emission area A, and a plurality of patterns 819 are illustrated and the light emitting diode ED and the emission area A are schematically illustrated. In the meantime, for the convenience of description, in FIG. 10A, the plurality of patterns 819 is omitted.

Referring to FIGS. 10A and 10B, the reflection plate RF is disposed so as to overlap the light emitting diode ED. The reflection plate RF may be disposed to have an area larger than an area of the bottom surface of the light emitting diode ED.

In the meantime, the reflection plate may be disposed to be asymmetric with respect to the center of the light emitting diode ED. For example, the center of the light emitting diode ED and a center of the reflection plate RF may be different and as illustrated in FIGS. 10A and 10B, the light emitting diode ED may be disposed to be leaned to one side of the reflection plate RF. Further, the reflection plate RF has an open area OPEN from which a partial area is removed. At this time, the open area OPEN of the reflection plate RF may be asymmetrical with respect to the center of the light emitting diode ED. For example, in FIGS. 10A and 10B, an area of the open area OPEN at the lower side of the light emitting diode ED may be larger than an area of the open area OPEN at the upper side of the light emitting diode ED. Therefore, an area of the reflection plate RF disposed on one side from the center of the light emitting diode ED and an area of the reflection plate RF disposed on the other side may be different.

FIGS. 11A and 11B are graphs for explaining an effect of a display device according to still another exemplary embodiment of the present disclosure. FIG. 11A is a graph for explaining a luminance distribution of a display device according to a comparative example and FIG. 11B is a graph for explaining a luminance distribution of a display device 800 according to still another exemplary embodiment of the present disclosure. In the display device according to the comparative example, a plurality of patterns 819 and the cover layer 860 are not disposed, which is different from the display device 800 according to another example of the present disclosure.

In the graph of FIGS. 11A and 11B, the X-axis indicates a viewing angle, and it is illustrated that a position matching the center of the light emitting diode ED is 0°, one direction of the light emitting diode ED is (+), and the other direction of the light emitting diode ED is (−). In the graphs of FIGS. 11A and 11B, the Y-axis indicates a luminance and the luminance in a front direction in the comparative example, that is, a luminance measured at 0° is set to be 1.

Referring to FIG. 11A, in the comparative example, it is confirmed that the luminance is higher in the lateral direction of −50° to −70° and in the lateral direction of 50° to 70° than in the front direction and a maximum luminance in one direction and a maximum luminance in the other direction are different. Specifically, referring to FIG. 11B, a maximum luminance of approximately 1.5 is obtained at a viewing angle of approximately 60° in one direction and a maximum luminance of approximately 1.3 is obtained at a viewing angle of approximately −50° in the other direction.

In contrast, referring to FIG. 11B, in the display device 800 according to still another exemplary embodiment of the present disclosure, the front luminance is approximately 1.35. Therefore, in the display device 800 according to still another exemplary embodiment of the present disclosure, it is confirmed that the front luminance is increased by approximately 0.35 as compared with the comparative example of FIG. 11A.

Further, referring to FIG. 11B, it is confirmed that the maximum luminance in the lateral direction is similar to the front luminance and there is almost no deviation between the maximum luminance in one direction and the maximum luminance in the other direction. Therefore, in the display device 800 according to still another exemplary embodiment of the present disclosure, it is confirmed that the viewing angle deviation is reduced more than the comparative example and the luminance asymmetry is improved.

In the display device 800 according to another exemplary embodiment of the present disclosure, a plurality of ring-shaped patterns 819 formed of a low refractive material is disposed below the cover layer 860 formed of a high refractive material to extract light which laterally travels in the front direction. Further, a display device 800 with a high color reproducibility, high luminance, and high efficiency may be implemented.

In the meantime, in the display device, a reflection plate which is disposed so as to overlap the light emitting diode is disposed. At this time, the reflection plate may be formed of various reflective material disposed on the display device. For example, in the display device, various electrodes or a wiring line itself disposed in the pixel circuit may be used as the reflection plate or the reflection plate may be formed of the same material as various electrodes or the wiring line disposed in the pixel circuit. Therefore, the reflection plate may be formed to be asymmetric with respect to the center of the light emitting diode according to a position of the pixel circuit and a position of the light emitting diode. Therefore, when the reflection plate is asymmetrically disposed, the luminance in a specific direction is increased and the viewing angle luminance distribution may be asymmetric.

Further, the emission area of the display device may be asymmetric with respect to the center of the light emitting diode. For example, when the light emitting diode is a lateral light emitting diode, the first electrode is disposed in an area excluding the active area. Therefore, in consideration of the placement of the first electrode, the active layer may be asymmetrically disposed, and the emission area may also be asymmetric. Accordingly, the maximum luminance in the area in which the first electrode is disposed is different from the maximum luminance in an area in which the second electrode is disposed.

In the display device 800 according to still another exemplary embodiment of the present disclosure, a plurality of patterns 819 are asymmetrically disposed in consideration of the emission area A and the luminance distribution of the light emitting diode ED. For example, a spaced distance between the plurality of patterns 819 in an area with a large luminance is smaller than a spaced distance between the plurality of patterns 819 in an area with a small luminance. Therefore, the viewing angle luminance deviation is improved, and the asymmetrical luminance is improved by adjusting the spaced distance between the plurality of patterns 819.

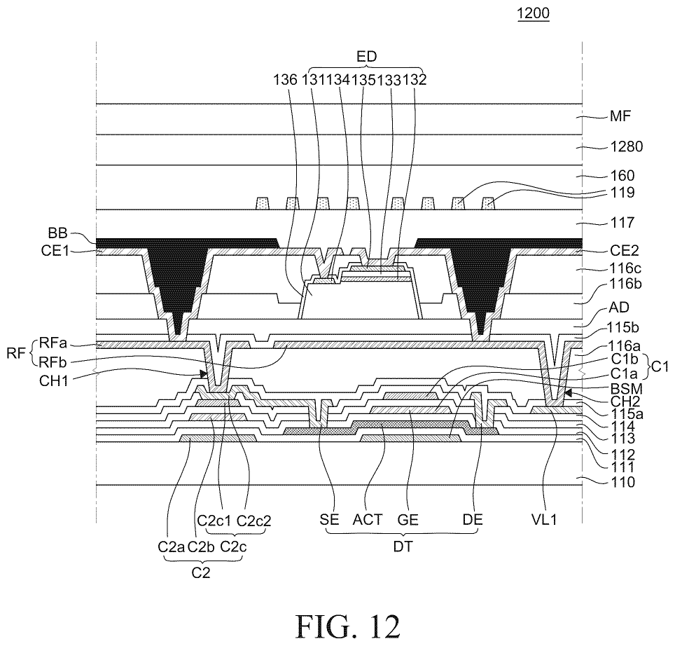

FIG. 12 is a cross-sectional view of a pixel area of a display device according to still another exemplary embodiment of the present disclosure. The only difference between the display device 1200 of FIG. 12 and the display device 100 of FIGS. 1 to 3B is that a scattering layer 1280 is added, but the other configurations are substantially the same, so that a redundant description will be omitted.

Referring to FIG. 12, a scattering layer 1280 is disposed on the cover layer 160. The scattering layer 1280 includes scattering particles to improve a light extraction efficiency. The scattering particles may be nano-sized spherical inorganic oxide particles having a light scattering property. The scattering particles may be, for example, one of titanium dioxide (TiO2) particles, silicon dioxide (SiO2) particles, zinc oxide (ZnO) particles, and aluminum oxide (AlO4) particles, but are not limited thereto. Further, the scattering particles may be spherical, porous, or fibrous, but are not limited thereto.

In the display device 1200 according to another exemplary embodiment of the present disclosure, a plurality of ring-shaped patterns 119 formed of a low refractive material is disposed below the cover layer 160 formed of a high refractive material to extract light which laterally travels in the front direction. Further, a display device 1200 with a high color reproducibility, high luminance, and high efficiency may be implemented.

Further, in the display device 1200 according to still another exemplary embodiment of the present disclosure, a scattering layer 1280 including scattering particles is disposed on the light emitting diode ED. Therefore, light emitted from the light emitting diode ED is reflected or scattered by the scattering layer 1280 to improve the light extraction efficiency.

The exemplary embodiments of the present disclosure can also be described as follows:

According to an aspect of the present disclosure, there is provided a display device. The display device comprises a substrate, a light emitting diode disposed on the substrate, a plurality of patterns which is disposed on the light emitting diode and has a ring shape, and a cover layer on the plurality of patterns, wherein the light emitting diode is a micro light emitting diode (micro-LED).

Spaced distances between the plurality of patterns may be the same.

A diameter of an outermost pattern, among the plurality of patterns, may be twice or more a diameter of the light emitting diode.

An innermost pattern, among the plurality of patterns, may be formed to enclose a circle having a diameter of 6 μm to 8 μm.

A width of a top surface of each of the plurality of patterns may be 3 μm.

An inclination angle formed by side surfaces of the plurality of patterns and bottom surfaces of the plurality of patterns may be 55 degrees or larger.

Top surfaces of the plurality of patterns may be recessed toward the substrate.

A spaced distance between the plurality of patterns disposed on one side from a center of the light emitting diode may be different from a spaced distance between the plurality of patterns disposed on the other side from the center of the light emitting diode.

The spaced distance between the plurality of patterns disposed on one side from the center of the light emitting diode may be smaller than the spaced distance between the plurality of patterns disposed on the other side from the center of the light emitting diode.

A second electrode of the light emitting diode may be disposed on one side of the light emitting diode and a first electrode of the light emitting diode may be disposed on the other side of the light emitting diode.

The display device may further comprise a reflection plate disposed below the light emitting diode, wherein the reflection plate may be asymmetric with respect to the light emitting diode.

A refractive index of the plurality of patterns may be lower than a refractive index of the cover layer.

The patterns are formed of a photoresist material and the cover layer may be formed of parylene.

The display device may further comprise a scattering layer which is disposed on the patterns and includes scattering particles.

According to another aspect of the present disclosure, there is provided a display device. The display device comprises a substrate, a plurality of transistors disposed on the substrate, a plurality of light emitting diodes which is connected to the plurality of transistors and is disposed on the plurality of transistors, a protection layer disposed on the plurality of light emitting diodes, and a plurality of patterns which is disposed on the protection layer so as to correspond to the plurality of light emitting diodes, wherein the plurality of light emitting diodes is micro light emitting diodes (micro LEDs).

Top surfaces of the plurality of patterns may be curved surfaces recessed toward the substrate.

A maximum luminance at one side of the light emitting diode may be higher than a maximum luminance at the other side of the light emitting diode and a spaced distance between the plurality of patterns disposed on one side of the light emitting diode may be smaller than a spaced distance between the plurality of patterns disposed on the other side of the light emitting diode.

The display device may further comprise a reflection plate which is disposed below the light emitting diode, an area disposed on one side from the center of the light emitting being different from an area disposed on the other side, wherein shapes of the plurality of patterns may be asymmetric.

The display device may further comprise a cover layer which covers the plurality of patterns, wherein a refractive index of the cover layer may be larger than a refractive index of the plurality of patterns.

The display device may further comprise a reflection plate disposed below a light emitting diode from the plurality of light emitting diode, wherein a length of the reflector plate extending to one side from the center of the light emitting diode may be smaller than a length of the reflector plate extending to the other side from the center of the light emitting diode.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but are not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate;
a light emitting diode on the substrate;
a plurality of patterns on the light emitting diode and in a ring shape; and
a cover layer on the plurality of patterns,
wherein the light emitting diode is a micro light emitting diode.

2. The display device according to claim 1, wherein
spacing between the plurality of patterns is same.

3. The display device according to claim 2, wherein a diameter of an outermost pattern, among the plurality of patterns, is at least twice a diameter of the light emitting diode.

4. The display device according to claim 2, wherein an innermost pattern, among the plurality of patterns, encloses a circle having a diameter of 6 μm to 8 μm.

5. The display device according to claim 2, wherein a width of a top surface of each of the plurality of patterns is 3 μm.

6. The display device according to claim 2, wherein an inclination angle between a side surface of at least one of the plurality of patterns and a bottom surface of at least one of the plurality of patterns is 55 degrees or larger.

7. The display device according to claim 1, wherein top surfaces of the plurality of patterns are recessed toward the substrate.

8. The display device according to claim 1, wherein a spaced distance between the plurality of patterns on one side from a center of the light emitting diode is different from a spaced distance between the plurality of patterns on a another side from the center of the light emitting diode.

9. The display device according to claim 8, wherein the spaced distance between the plurality of patterns on one side from the center of the light emitting diode is smaller than the spaced distance between the plurality of patterns on another side from the center of the light emitting diode.

10. The display device according to claim 9, wherein a second electrode of the light emitting diode is on one side of the light emitting diode and a first electrode of the light emitting diode is on another side of the light emitting diode.

11. The display device according to claim 8, further comprising:
a reflection plate below the light emitting diode,
wherein the reflection plate is asymmetric with respect to the center of the light emitting diode.

12. The display device according to claim 1, wherein a refractive index of the plurality of patterns is lower than a refractive index of the cover layer.

13. The display device according to claim 1, wherein the plurality of patterns comprise a photoresist material and the cover layer comprises parylene.

14. The display device according to claim 1, further comprising:
a scattering layer on the plurality of patterns, the scattering layer including scattering particles.

15. A display device, comprising:
a substrate;
a plurality of transistors on the substrate;
a plurality of light emitting diodes connected to the plurality of transistors and disposed on the plurality of transistors;
a protection layer on the plurality of light emitting diodes; and
a plurality of patterns on the protection layer, the plurality of patterns corresponding to the plurality of light emitting diodes,
wherein the plurality of light emitting diodes are micro light emitting diodes.

16. The display device according to claim 15, wherein top surfaces of the plurality of patterns are curved surfaces recessed toward the substrate.

17. The display device according to claim 15, wherein a maximum luminance at one side of a light emitting diode from the plurality of light emitting diodes is higher than a maximum luminance at another side of the light emitting diode and a spaced distance between the plurality of patterns on the one side of the light emitting diode is smaller than a spaced distance between the plurality of patterns on the other side of the light emitting diode.

18. The display device according to claim 15, further comprising:
a reflection plate below a light emitting diode from the plurality of light emitting diodes,
wherein the reflection plate is asymmetric with respect to a center of the light emitting diode, and shapes of the plurality of patterns are asymmetric with respect to the center of the light emitting diode.

19. The display device according to claim 15, further comprising:
a cover layer that covers the plurality of patterns,
wherein a refractive index of the cover layer is larger than a refractive index of the plurality of patterns.

20. The display device according to claim 15, further comprising:
a reflection plate disposed below a light emitting diode from the plurality of light emitting diode,
wherein a length of the reflector plate extending to one side from the center of the light emitting diode is smaller than a length of the reflector plate extending to the other side from the center of the light emitting diode.
